(19) United States
(12) Patent Application Publication
(10) Pub. No.: US 2025/0323667 A1
(43) Pub. Date: Oct. 16, 2025

(54) RESOURCE ALLOCATION METHOD, APPARATUS, DEVICE AND STORAGE MEDIUM

(71) Applicant: BEIJING XIAOMI MOBILE SOFTWARE CO., LTD., Beijing (CN)

(72) Inventors: Zhenyu ZHANG, Beijing (CN); Wei HONG, Beijing (CN); Yumin WU, Beijing (CN)

(21) Appl. No.: 18/865,092

(22) PCT Filed: May 12, 2022
(86) PCT No.: PCT/CN2022/092557

§ 371 Date: Nov. 12, 2024

(51) Int. Cl. H03M 13/27; H04W 72/04

(52) U.S. Cl. CPC H03M 13/2739; H04W 72/04

(57) ABSTRACT

A method for resource allocation is applied to user equipment or a network side device. The method includes: determining a resource allocation scheme, the resource allocation scheme being performing resource allocation based on a cubic permutation polynomial (CPP) interleaver; performing resource allocation according to the resource allocation scheme; and sending configuration information, wherein the configuration information is used to determine an allocated resource.

### CROSS REFERENCE TO RELATED APPLICATIONS

The present application is a U.S. National Stage of International Application No. PCT/CN2022/092557, filed on May 12, 2022, the content of which is incorporated herein by reference in its entirety.

### TECHNICAL FIELD

The present disclosure relates to the field of communication technologies, and in particular, to a method and apparatus for resource allocation, a device, and a storage medium.

### BACKGROUND

In recent years, with the increasing shortage of spectrum resources, rapid development of a large number of spectrum sharing technologies is promoted. Since radar and communication functions usually have different frequency bands, the shortage of spectrum resources promotes organic fusion of radar and communication functions, that is, an Integrated Sensing and Communication (ISAC) system. The ISAC system is established on the basis of the organic fusion of the radar system and the communication system, because the radar system and the communication system have a plurality of commonalities, for example, they can share hardware devices such as a common radio frequency front end, frequency domain signal processing algorithms are similar, and waveform designs are similar, or the like.

### SUMMARY

According to embodiments of a first aspect of the present disclosure, there is provided a method for resource allocation, including:
determining a resource allocation scheme as performing resource allocation based on a cubic permutation polynomial (CPP) interleaver;
performing resource allocation according to the resource allocation scheme; and
sending configuration information, where the configuration information is used to determine an allocated resource.

According to embodiments of another aspect of the present disclosure, there is provided a communication apparatus, where the apparatus includes a processor and a memory. The memory stores a computer program, and the processor executes the computer program stored in the memory to cause the apparatus to perform the method provided in the embodiments of the first aspect.

According to embodiments of another aspect of the present disclosure, there is provided a non-transitory computer-readable computer-readable storage medium configured to store an instruction that, when executed, causes the method provided in the embodiments of the first aspect to be implemented.

### BRIEF DESCRIPTION OF THE DRAWINGS

The above and/or additional aspects and advantages of the present disclosure will become apparent and more readily appreciated from the following descriptions made with reference to the accompanying drawings, in which:

FIG. 1 and FIG. 2 are schematic diagrams of time-frequency resources for a data receiving end #A, a data receiving end #B, a data receiving end #C, and a data receiving end #D in the related art;

FIG. 3 is a perspective view and a plan view of radar detection on a data receiving end #A, a data receiving end #B, a data receiving end #C, and a data receiving end #D by a base station using the allocation method shown in FIG. 1;

FIG. 4 is a perspective view and a plan view of radar detection on a data receiving end #A, a data receiving end #B, a data receiving end #C, and a data receiving end #D by a base station using the allocation method shown in FIG. 2;

FIG. 5 is a schematic flowchart of a method for resource allocation provided according to some embodiments of the present disclosure;

FIG. 6 is a schematic flowchart of a method for resource allocation provided according to some embodiments of the present disclosure;

FIG. 7a is a schematic flowchart of a method for resource allocation provided according to some embodiments of the present disclosure;

FIG. 7b is a schematic diagram of time-frequency resources for UE #A when resource allocation is performed by using the method shown in FIG. 7a provided according to some embodiments of the present disclosure;

FIG. 7c is a perspective view and a plan view of radar detection on UE by using the method shown in FIG. 7a provided according to some embodiments of the present disclosure;

FIG. 8a is a schematic flowchart of a method for resource allocation provided according to some embodiments of the present disclosure;

FIG. 8b is a schematic diagram of time-frequency resources for UE #A when resource allocation is performed by using the method shown in FIG. 8a provided according to some embodiments of the present disclosure;

FIG. 8c is a perspective view and a plan view of radar detection on UE by using the method shown in FIG. 8a provided according to some embodiments of the present disclosure;

FIG. 9 is a schematic structural diagram of an apparatus for data sending provided according to some embodiments of the present disclosure;

FIG. 10 is a schematic structural diagram of an apparatus for data receiving provided according to some embodiments of the present disclosure;

FIG. 11 is a schematic structural diagram of an apparatus for echo receiving provided according to some embodiments of the present disclosure;

FIG. 12 is a block diagram of user equipment provided according to some embodiments of the present disclosure;

FIG. 13 is a block diagram of a network side device provided according to some embodiments of the present disclosure.

### DETAILED DESCRIPTION

Example embodiments will now be described in detail here, examples of which are illustrated in the accompanying drawings. The following description refers to the accompanying drawings in which the same numbers in different drawings represent the same or similar elements unless otherwise represented. The implementations described in the following example embodiments do not represent all implementations consistent with the embodiments of the present disclosure. By contrast, they are merely examples of apparatuses and methods consistent with some aspects of the embodiments of the present disclosure as detailed in the appended claims.

Terms used in the embodiments of the present disclosure are merely for the purpose of describing particular embodiments, and are not intended to limit the embodiments of the present disclosure. The singular forms “a” and “the” used in the embodiments of the present disclosure and the appended claims are also intended to include plural forms, unless the context clearly indicates other meanings. It should also be understood that the term “and/or” as used here refers to and includes any or all possible combinations of one or more associated listed items.

It should be understood that although the terms first, second, third, etc., may be used in the embodiments of the present disclosure to describe various information, these information should not be limited to these terms. These terms are only used to distinguish the same type of information from each other. For example, without departing from the scope of the embodiments of the present disclosure, the first information may also be referred to as second information; and similarly, the second information may also be referred to as first information. Depending on the context, the words “if” and “in a case” as used herein may be interpreted as “at the time that . . . ” or “when . . . ” or “in response to determining . . . ”.

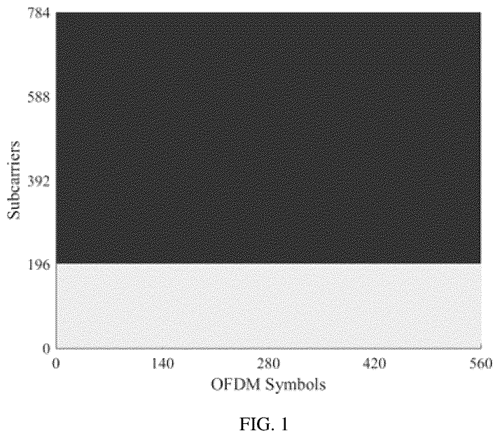

In the related art, when there are a plurality of data receiving ends in the ISAC system, how to perform subcarrier allocation is also a problem to be studied. A simple and feasible method is to adopt subcarrier continuous allocation, in which a certain data receiving end occupies a part of continuous spectrum resources, and other data receiving ends occupy other continuous spectrum resources. Among them, it is assumed that the total quantity of subcarriers corresponding to a symbol is 784, and there are four data receiving ends in the ISAC system, which are respectively a data receiving end #A, a data receiving end #B, a data receiving end #C, and a data receiving end #D. FIG. 1 and FIG. 2 are schematic diagrams of time-frequency resources for the data receiving end #A in the related art. Subcarrier positions within different orthogonal frequency division multiplexing (OFDM) symbol times in FIG. 1 are constant, and subcarrier positions within different OFDM symbol times in FIG. 2 are randomly changed. In addition, the subcarrier occupied by the data receiving end #A in FIG. 1 and FIG. 2 is represented by a white portion, and the subcarrier not occupied by the data receiving end #A is represented by a black portion.

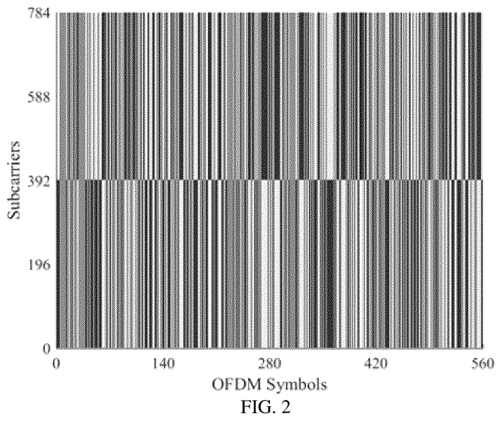

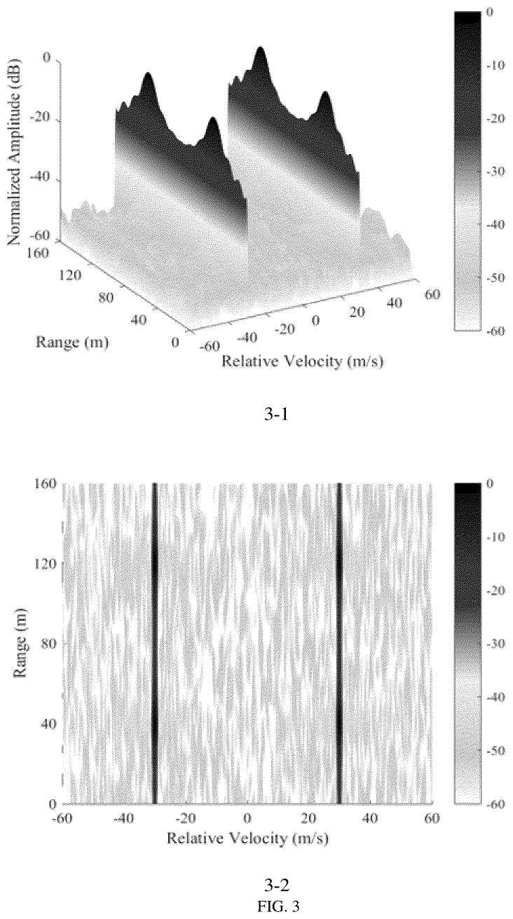

However, the method in the related art may cause the signal correlation between the subcarriers for the data receiving end to be relatively greater, thus affecting the detection effect on each data receiving end. Specifically, when the modulation mode is the quadrature phase shift keying (QPSK), and the signal to noise ratio (SNR) is set to 0 dB, FIG. 3 is a perspective view and a plan view of radar detection on the data receiving end #A, the data receiving end #B, the data receiving end #C, and the data receiving end #D by the base station using the allocation method shown in FIG. 1, where the perspective view of radar detection is 3-1 in FIG. 3, and the plan view of radar detection is 3-2 in FIG. 3; and FIG. 4 is a perspective view and a plan view of radar detection on the data receiving end #A, the data receiving end #B, the data receiving end #C, and the data receiving end #D by the base station using the allocation method shown in FIG. 2, where the perspective view of radar detection is 4-1 in FIG. 4, and the plan view of radar detection is 4-2 in FIG. 4. As can be seen from FIG. 3 and FIG. 4, after frequency domain resources are allocated to the data receiving end by using the allocation mode shown in FIG. 1, there is a distance expansion phenomenon on the distance axis (i.e., the longitudinal axis) when the data receiving end is detected; after frequency domain resources are allocated to the data receiving end by using the allocation mode shown in FIG. 2, there is a velocity expansion phenomenon on the velocity axis (i.e., the horizontal axis) when the data receiving end is detected; the secondary peak is relatively higher, and there are more side lobes, thus the detection effect is not ideal, and the distance and velocity of the data receiving end cannot be accurately detected.

The method and apparatus for resource allocation, device, and storage medium provided in the embodiments of the present disclosure are described in detail below with reference to the accompanying drawings.

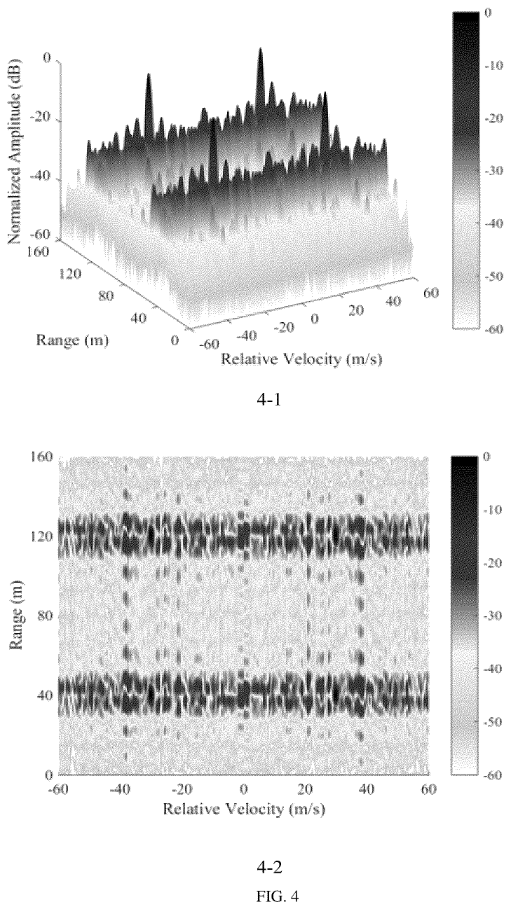

FIG. 5 is a schematic flowchart of a method for resource allocation provided according to some embodiments of the present disclosure. As shown in FIG. 5, the method for resource allocation may include the following steps.

In step 501, a resource allocation scheme is determined as performing resource allocation based on a CPP interleaver.

The method according to the embodiments of the present disclosure may be applied to an active radar system and/or a passive radar system, where the active radar system and the passive radar system may both include a data sending end, a data receiving end, and an echo receiving end. Among them, a base station or user equipment (UE) may serve as a data sending end and an echo receiving end, and UE may serve as a data receiving end.

Furthermore, in an active radar system, a same device may serve as a data sending end and an echo receiving end at the same time. In a passive radar system, different devices may respectively serve as a data sending end and an echo receiving end, and there may be a plurality of echo receiving ends. Among them, the data sending end sends bit data to the data receiving end, and the data receiving end serves as a receiver to complete a communication function. The echo signal generated due to that the bit data sent by the data sending end is irradiated on the data receiving end is transmitted back to the echo receiving end (i.e., the data sending end), and the echo receiving end performs information (such as, velocity and distance) detection on the data receiving end through the radar processor to complete a radar function.

It should be noted that, in some embodiments of the present disclosure, the UE may be a device that provides voice and/or data connectivity to the user. The terminal device may communicate with one or more core networks via a radio access network (RAN). The UE may be an Internet of Things terminal, such as a sensor device, a mobile phone (or referred to as a “cellular” phone), and a computer having an IoT terminal; for example, it may be a fixed, portable, pocket-sized, handheld, computer-built-in, or vehicle-mounted device, such as, a station (STA), a subscriber unit, a subscriber station, a mobile station, a mobile, a remote station, an access point, a remote terminal, an access terminal, a user terminal, or a user agent. Alternatively, the UE may also be a device of an unmanned aerial vehicle. Alternatively, the UE may be a vehicle-mounted device; for example, it may be a trip computer having a wireless communication function, or a wireless terminal externally connected to a trip computer. Alternatively, the UE may be a roadside device; for example, it may be a street lamp, a signal lamp, or another roadside device with a wireless communication function, etc.

Furthermore, in some embodiments of the present disclosure, the above method for determining the resource allocation scheme may include at least one of the following.

The resource allocation scheme sent by a network device (a base station and/or a core network device) is obtained.

The resource allocation scheme sent by a base station is obtained, where the resource allocation scheme is pre-configured by a core network device to the base station.

The resource allocation scheme sent by a base station is obtained, where the resource allocation scheme is pre-configured by another base station to the base station. The resource allocation scheme is determined based on a protocol agreement.

The resource allocation scheme is determined by itself; that is, the configuration scheme to be adopted is determined by itself according to actual situations or requirements.

In step 502, resource allocation is performed according to the resource allocation scheme.

In some embodiments of the present disclosure, a CPP interleaver is mainly used to perform frequency domain resource allocation on the data receiving end in the ISAC system. Among them, this part of content will be described in detail in the following embodiments.

In step 503, configuration information is sent, where the configuration information is used to determine an allocated resource.

In some embodiments of the present disclosure, the configuration information may include frequency domain resources corresponding to each data receiving end.

In summary, in the method for resource allocation provided in the embodiments of the present disclosure, a resource allocation scheme is firstly determined as performing resource allocation based on a CPP interleaver; and then, resource allocation is performed according to the resource allocation scheme, and configuration information is sent, where the configuration information is used to determine an allocated resource. It can be seen that, in the embodiments of the present disclosure, a CPP interleaver is introduced when a resource is allocated to a data receiving end, the subcarrier sequence is scrambled by using the CPP interleaver, and the subcarriers are randomly allocated to a plurality of users by constructing a pseudo-random sequence, so that continuous frequency domain resources are prevented from being allocated to the data receiving end, and the sensing capability of the ISAC system is improved, which is more conducive to distinguishing a plurality of moving targets in the ISAC system.

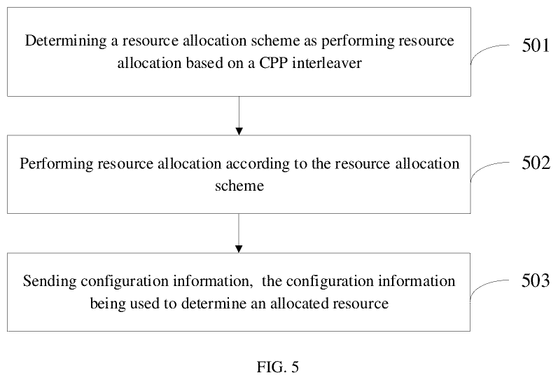

FIG. 6 is a schematic flowchart of a method for resource allocation provided according to some embodiments of the present disclosure. As shown in FIG. 6, the method for resource allocation may include the following steps.

In step 601, a resource allocation scheme is determined as performing resource allocation based on a CPP interleaver.

For detailed descriptions of step 601, reference may be made to the description of the foregoing embodiments, and details are not described here in the embodiments of the present disclosure.

In step 602, a first subcarrier index sequence is obtained by sequentially arranging N subcarrier indexes in a symbol (such as, an orthogonal frequency division multiplexing (OFDM) symbol).

In some embodiments of the present disclosure, the N subcarrier indexes in a symbol may be arranged in an ascending order or a descending order. For example, the obtained first subcarrier index sequence may be (0, 1, . . . , N−1).

In step 603, a second subcarrier index sequence is obtained by performing interleaving processing on the first subcarrier index sequence by using a CPP interleaver. In some embodiments of the present disclosure, the method for interleaving processing may mainly include the following steps.

In step a, an interleaving parameter of the CPP interleaver is determined.

In some embodiments of the present disclosure, the interleaving parameter of the CPP interleaver may include at least one of the following:
a CPP interleaver calculation formula;
a decomposition formula corresponding to the CPP interleaver; or
a parameter value rule in the CPP interleaver calculation formula.

Specifically, the above CPP interleaver calculation formula may be as follows:

$$π ( i ) = ( {f}_{1} \cdot i + {f}_{2} \cdot {i}^{2} + {f}_{3} \cdot {i}^{3} ) mod N \qquad ( 1 )$$

where, i is used to indicate the i^{th} bit in the second subcarrier index sequence, π(i) is the value of the i^{th} bit in the second subcarrier index sequence, f₁, f₂ and f₃ are three parameters of the CPP interleaver, and values of f₁, f₂ and f₃ are determined based on the parameter value rule.

The decomposition formula corresponding to the CPP interleaver may be as follows:

$$N = {\prod }_{i = 1}^{ω ( N )} {p}_{i}^{{α}_{N , i}} \qquad ( 2 )$$

where, ω(N) is a positive integer, pᵢ is a factor of N, α_{N,i} is a corresponding index.

The parameter value rule may be as follows.

| | | |
|---|---|---|
| p₁ = 2 | α_{N, 1} = 1 | (f₁ + f₂ + f₃) = 1 mod 2 |
| | α_{N, 1} > 1 | f₁ = 1 mod 2, f₂ = 0 mod 2, f₃ = 0 mod 2 |
| P₂ = 3 | α_{N, 2} = 1 | (f₁ + f₃) ≠ 0 mod 3, f₂ = 0 mod 3 |
| | α_{N, 2} > 1 | f₁ ≠ 0 mod 3, (f₁ + f₃) ≠ 0 mod 3, f₂ = 0 mod 3 |
| 3 \| (pᵢ − 1) | α_{N, i} ≥ 1 | f₁ ≠ 0 mod pᵢ, f₂ = 0 mod pᵢ, f₃ = 0 mod pᵢ |
| 3 ł (pᵢ − 1) | α_{N, i} = 1 | f₂² = 3 · f₁ · f₃ mod pᵢ, if f₃ ≠ 0 mod pᵢ |
| pᵢ > 3 | | f₁ ≠ 0 mod pᵢ, f₂ = 0 mod pᵢ, if f₃ = 0 mod pᵢ |
| | α_{N, i} > 1 | f₁ ≠ 0 mod pᵢ, f₂ = 0 mod pᵢ, f₃ = 0 mod pᵢ |

It can be seen from the above parameter value rule that, in the case of 3|(pᵢ−1) and α_{K,i}≥1, values of f₁, f₂ and f₃ need to satisfy the parameter value rule of f₁≠0 mod pᵢ, f₂=0 mod pᵢ, f₃=0 mod pᵢ. In the case of p₁=2, α_{N,1}>1, p₂=3 and α_{N,2}=1, values of f₁, f₂ and f₃ need to satisfy the parameter value rule of f₁=1 mod 2, f₂=0 mod 2, f₃=0 mod 2 and (f₁+f₃)≠0 mod 3, f₂=0 mod 3.

In some embodiments of the present disclosure, the above method for determining the interleaving parameter of the CPP interleaver may include at least one of the following.

An interleaving parameter of the CPP interleaver sent by a network device is obtained.

An interleaving parameter of the CPP interleaver sent by a base station is obtained, where the interleaving parameter of the CPP interleaver is pre-configured by a core network device to the base station.

An interleaving parameter of the CPP interleaver sent by a base station is obtained, where the interleaving parameter of the CPP interleaver is pre-configured by another base station to the base station.

An interleaving parameter of the CPP interleaver is determined based on a protocol agreement.

In step b, values of pᵢ and α_{N,i} are determined by performing decomposition on the N based on the decomposition formula.

In some embodiments of the present disclosure, assuming that N=12, N may be decomposed as N=12=2²*3 based on the decomposition formula (2). In this case, it may be determined that p₁=2, p₂=3, α_{N,1} is 2 (i.e., α_{N,1}>1), and α_{N,2}=1.

In step c, values of f₁, f₂ and f₃ are determined based on the parameter value rule and the values of pᵢ and α_{N,i}.

Specifically, the parameter value rule that needs to be satisfied by the values of f₁, f₂ and f₃ may be determined based on the values of pᵢ and α_{N,i}. Then, values of f₁, f₂ and f₃ may be determined based on the parameter value rule that needs to be satisfied by the values of f₁, f₂ and f₃.

For example, assuming that N is 12 and is decomposed as N=12=2²*3, it may be determined that f₁=557, f₂=120 and f₃=600.

In step d, a second subcarrier index sequence is obtained by calculating based on the CPP interleaver calculation formula.

Specifically, the values of f₁, f₂ and f₃ determined in step c may be substituted into the CPP interleaver calculation formula (1), and the second subcarrier index sequence may be obtained by calculating based on the CPP interleaver calculation formula (1).

For example, assuming that the non-interleaved first subcarrier index sequence is (0, 1, 2, 3, 4, 5, 6, 7, 8, 9, 10, 11), and the interleaving parameter of the CPP interleaver is set as f₁=557, f₂=120 and f₃=600, the second subcarrier index sequence may be (0, 5, 10, 3, 8, 1, 6, 11, 4, 9, 2, 7).

In step 604, K subcarrier groups are obtained by dividing the subcarrier indexes in the second subcarrier index sequence to perform grouping, where K is a quantity of data receiving ends in the ISAC system, and each subcarrier group includes at least one first subcarrier index sequence.

It should be noted that, in some embodiments of the present disclosure, the K subcarrier groups should satisfy the following conditions.

In response to N being divisible by K, the quantity of subcarrier indexes included in each of the K subcarrier groups are the same (for example, the quantity may be a value obtained by dividing N by K).

In response to N being not divisible by K, the quantity of subcarrier indexes included in each of d subcarrier groups among the K subcarrier groups is the same, the quantity of subcarrier indexes included in each of other subcarrier groups is the same, and the quantity of subcarrier indexes included in each of the d subcarrier groups is greater than the quantity of subcarrier indexes included in each of other subcarrier groups by 1, where d is a value obtained by performing a modulo operation on K by using N. In addition, the quantity of subcarrier indexes included in each of the d subcarrier groups may be 1 plus an integer of the quotient of N divided by K; and the quantity of subcarrier indexes included in each of other subcarrier groups may be the integer of the quotient of N divided by K.

In some embodiments of the present disclosure, assuming that N is 12, K is 3, where N may be divided by K, the second subcarrier index sequence may be divided into 3 subcarrier groups, and the quantity of subcarrier indexes included in each of these 3 subcarrier groups is the same, for example, it may be 4. On this basis, assuming that (0, 5, 10, 3, 8, 1, 6, 11, 4, 9, 2, 7) is the second subcarrier index sequence, the first 4 subcarrier indexes in the second subcarrier index sequence may be divided as a subcarrier group #1, which is (0, 5, 10, 3); the 5th to 8th subcarrier indexes in the second subcarrier index sequence may be divided as a subcarrier group #2, which is (8, 1, 6, 11); and the 9th to 12th subcarrier indexes in the second subcarrier index sequence may be divided as a subcarrier group #3, which is (4, 9, 2, 7).

In some embodiments of the present disclosure, assuming that N is 12, K is 7, where N is not divisible by K, it is determined that the value d=5 which is obtained by performing a modulo operation on K by using N. In this case, the second subcarrier index sequence may be divided into 7 subcarrier groups, and the quantity of subcarrier indexes included in each of certain 5 subcarrier groups is the same, and the quantity of subcarrier indexes included in each of the remaining 2 subcarrier groups among the 7 subcarrier groups is different from the quantity of subcarrier indexes included in each of the certain 5 subcarrier groups. At the same time, the quantity of subcarrier indexes included in each of the certain 5 subcarrier groups is greater than the quantity of subcarrier indexes included in each of the remaining 2 subcarrier groups by 1. On this basis, assuming that (0, 5, 10, 3, 8, 1, 6, 11, 4, 9, 2, 7) is the second subcarrier index sequence, then the first 2 subcarrier indexes in the second subcarrier index sequence may be divided as a subcarrier group #1, which is (0, 5); the 3th to 4th subcarrier indexes in the second subcarrier index sequence may be divided as a subcarrier group #2, which is (10, 3); the 5th to 6th subcarrier indexes in the second subcarrier index sequence may be divided as a subcarrier group #3, which is (8, 1); the 7th to 8th subcarrier indexes in the second subcarrier index sequence may be divided as a subcarrier group #4, which is (6, 11); the 9th to 10th subcarrier indexes in the second subcarrier index sequence may be divided as a subcarrier group #5, which is (4, 9); the 11th subcarrier index in the second subcarrier index sequence may be divided as a subcarrier group #6, which is (2); and the 12th subcarrier index in the second subcarrier index sequence may be divided as a subcarrier group #7, which is (7).

Alternatively, the 1th subcarrier index and the 5th subcarrier index counting from the bottom in the second subcarrier index sequence may be divided as a subcarrier group #1, which is (0, 11); the 2th subcarrier index and the 4th subcarrier index counting from the bottom in the second subcarrier index sequence may be divided as a subcarrier group #2, which is (5, 4); the 3th subcarrier index and the 3th subcarrier index counting from the bottom in the second subcarrier index sequence may be divided as a subcarrier group #3, which is (10, 9); the 4th subcarrier index and the 2th subcarrier index counting from the bottom in the second subcarrier index sequence may be divided as a subcarrier group #4, which is (3, 2); the 5th subcarrier index and the last subcarrier index in the second subcarrier index sequence may be divided as a subcarrier group #5, which is (8, 7); the 6th subcarrier index in the second subcarrier index sequence may be divided as a subcarrier group #6, which is (1); and the 7th subcarrier index in the second subcarrier index sequence may be divided as a subcarrier group #7, which is (6).

In other words, in the embodiments of the present disclosure, the subcarrier indexes in the second subcarrier index sequence may be divided into K subcarrier groups according to an order from front to back, or not according to the order from front to back.

In step 605, a subcarrier group is allocated to each data receiving end, where a subcarrier corresponding to a subcarrier index in each subcarrier group is a frequency domain resource allocated to the data receiving end.

In some embodiments of the present disclosure, the kth subcarrier group may be allocated to the kth data receiving end. For example, it is assumed that there are two data receiving ends in the ISAC system, which are a data receiving end #A and a data receiving end #B, respectively, and the obtained K subcarrier groups are the subcarrier group #1 and the subcarrier group #2, then the subcarrier group #1 may allocated to the data receiving end #A, and the subcarrier group #2 may be allocated to the data receiving end #B. In this case, the frequency domain resource for the data receiving end #A is the subcarrier corresponding to the subcarrier index in the subcarrier group #1, and the frequency domain resource for the data receiving end #B is the subcarrier corresponding to the subcarrier index in the subcarrier group #2.

In step 606, configuration information is sent, where the configuration information is used to determine an allocated resource.

In some embodiments of the present disclosure, the configuration information may include the frequency domain resources corresponding to various data receiving end. For example, the configuration information includes that the subcarrier group #1 is the frequency domain resource for the data receiving end #A, and the subcarrier group #2 is the frequency domain resource for the data receiving end #B.

It can be learned from the foregoing steps 602 and 603 that, in the embodiments of the present disclosure, a second subcarrier index sequence may be obtained by performing interleaving processing on the first subcarrier index sequences that are sequentially arranged by using a CPP interleaver to scramble the sequence, where the subcarrier indexes in the second subcarrier index sequence are not arranged in sequence. Then, the subcarrier groups are obtained by grouping the second subcarrier index sequence through performing steps 604 and 605, and the subcarrier group is allocated to the data receiving end. Among them, since the subcarrier indexes in the second subcarrier index sequence are not arranged in sequence, the subcarrier indexes in the subcarrier groups obtained by grouping should also not be arranged in sequence, so that discontinuous subcarriers may be allocated to each data receiving end. When the data receiving end performs communication based on the discontinuous subcarriers subsequently, the signal correlation between the various subcarriers for the data receiving end may be reduced, and the detection effect on the data receiving end is ensured.

In addition, in the embodiments of the present disclosure, when performing interleaving processing by using an interleaver based on a permutation polynomial (PP), since the interleaver algorithm based on the PP has a complete algebraic structure, high-efficiency hardware implementation (fast velocity and small storage amount) and a good bit error rate (BER) performance, the efficiency and accuracy of the interleaving processing may be ensured, thus ensuring that resource allocation may be efficiently and accurately performed subsequently.

In summary, in the method for resource allocation provided in the embodiments of the present disclosure, a resource allocation scheme is firstly determined as performing resource allocation based on a CPP interleaver; and then, resource allocation is performed according to the resource allocation scheme, and configuration information is sent, where the configuration information is used to determine an allocated resource. It can be seen that, in the embodiments of the present disclosure, a CPP interleaver is introduced when a resource is allocated to a data receiving end, the subcarrier sequence is scrambled by using the CPP interleaver, and the subcarriers are randomly allocated to a plurality of users by constructing a pseudo-random sequence, so that continuous frequency domain resources are prevented from being allocated to the data receiving end, and the sensing capability of the ISAC system is improved, which is more conducive to distinguishing a plurality of moving targets in the ISAC system.

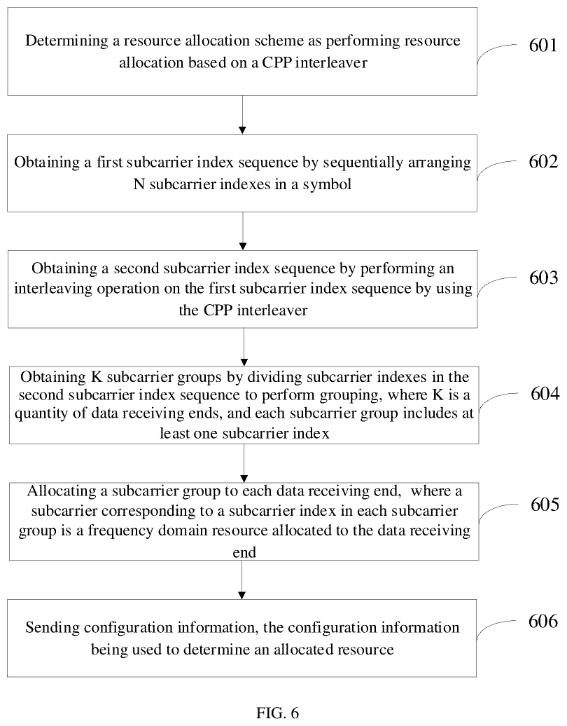

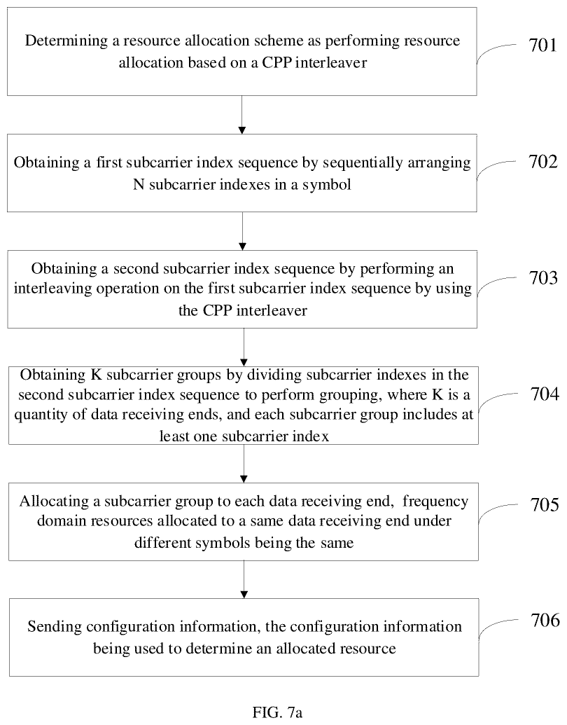

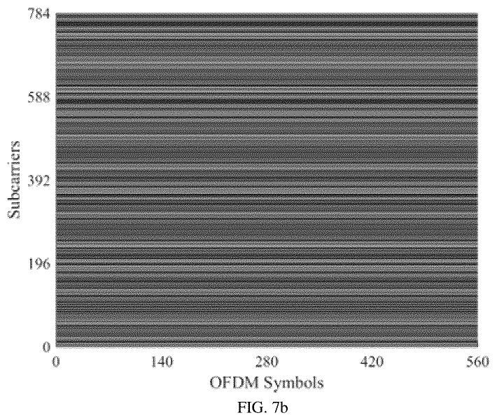

FIG. 7a is a schematic flowchart of a method for resource allocation provided according to some embodiments of the present disclosure. As shown in FIG. 7a, the method for resource allocation may include the following steps.

In step 701, a resource allocation scheme is determined as performing resource allocation based on a CPP interleaver.

In step 702, a first subcarrier index sequence is obtained by sequentially arranging N subcarrier indexes in a symbol.

In step 703, a second subcarrier index sequence is obtained by performing interleaving processing on the first subcarrier index sequence by using the CPP interleaver.

In step 704, K subcarrier groups are obtained by dividing subcarrier indexes in the second subcarrier index sequence to perform grouping, where k is a quantity of data receiving ends in the ISAC system, and each subcarrier group includes at least one first subcarrier index sequence.

For detailed descriptions of steps 701 to 704, reference may be made to the description of the foregoing embodiments, and details are not described here in the embodiments of the present disclosure.

In step 705, a subcarrier group is allocated to each data receiving end, where a subcarrier corresponding to a subcarrier index in each subcarrier group is a frequency domain resource allocated to the data receiving end, and frequency domain resources allocated to the same data receiving end under different symbols are the same.

In some embodiments of the present disclosure, it is assumed that the basic parameters of the ISAC system are shown in Table 1, and it is assumed that there are two UE of A and B in the ISAC system as the data receiving ends, and the velocity and distance information of the two UE are as shown in Table 2.

TABLE 1
Basic Parameters of the ISAC System

| Parameter Name | Numerical Value | |
|---|---|---|
| Carrier frequency | 24 | GHz |
| Subcarrier interval | 60 | kHz |
| Quantity of subcarriers | 784 | |
| Total Symbol Bandwidth | 47 | MHz |
| Quantity of OFDM symbols | 560 | |
| OFDM prefix duration | 1.17 | us |
| OFDM Symbol Time | 16.67 | us |
| Full OFDM Symbol Duration | 17.84 | us |

| | |
|---|---|
| BS (Base Station) Antenna Quantity | 1 |
| UE Antenna Quantity | 1 |

TABLE 2
Velocity Information and Distance Information of UE

| UE | Distance (m) | Velocity (m/s) |
|---|---|---|
| A | 120 | −30 |
| B | 120 | 30 |
| C | 40 | −30 |
| D | 40 | 30 |

Based on the basic parameters in Table 1, it may be determined that UE #A, UE #B, UE #C, and UE #D respectively occupy 196 subcarriers among N=784 subcarriers, and subcarrier indexes of UE #A, UE #B, UE #C, and UE #D are obtained through calculating by a CPP interleaver, and subcarrier indexes of UE #A, UE #B, UE #C, and UE #D are unchanged within 560 OFDM symbol times. Among them, FIG. 7b is a schematic diagram of time-frequency resources for UE #A when resource allocation is performed by using the method shown in FIG. 7a provided according to embodiments of the present disclosure, where a subcarrier occupied by the UE #A is represented by a white portion, and a subcarrier that is not occupied by the UE #A is represented by a black portion. It should be noted that, FIG. 7b is a schematic diagram obtained when resource allocation is performed based on a CPP interleaver calculation formula in a case that f₁=293, f₂=756, f₃=896, and FIG. 7c is a perspective view and a plan view of radar detection on UE by using the method shown in FIG. 7a provided according to embodiments of the present disclosure, where the perspective view of radar detection is c-1 in FIG. 7c, and the plan view of radar detection plan is c-2 in FIG. 7c. It can be seen from FIG. 7c that, after the frequency domain resource is allocated to the UE by using the allocation mode shown in FIG. 7a, when detecting on the UE, although the side lobe is obvious, the distance expansion phenomenon on the distance axis (i.e., the longitudinal axis) is obviously relieved, thus ensuring the detection effect to a certain extent.

In step 706, configuration information is sent, where the configuration information is used to determine an allocated resource.

In some embodiments of the present disclosure, the configuration information may include frequency domain resources corresponding to various data receiving end. For example, the configuration information includes that the subcarrier group #1 is a frequency domain resource for the data receiving end #B.

In summary, in the method for resource allocation provided in the embodiments of the present disclosure, a resource allocation scheme is firstly determined as performing resource allocation based on a CPP interleaver; and then, resource allocation is performed according to the resource allocation scheme, and configuration information is sent, where the configuration information is used to determine an allocated resource. It can be seen that, in the embodiments of the present disclosure, a CPP interleaver is introduced when a resource is allocated to a data receiving end, the subcarrier sequence is scrambled by using the CPP interleaver, and the subcarriers are randomly allocated to a plurality of users by constructing a pseudo-random sequence, so that continuous frequency domain resources are prevented from being allocated to the data receiving end, and the sensing capability of the ISAC system is improved, which is more conducive to distinguishing a plurality of moving targets in the ISAC system.

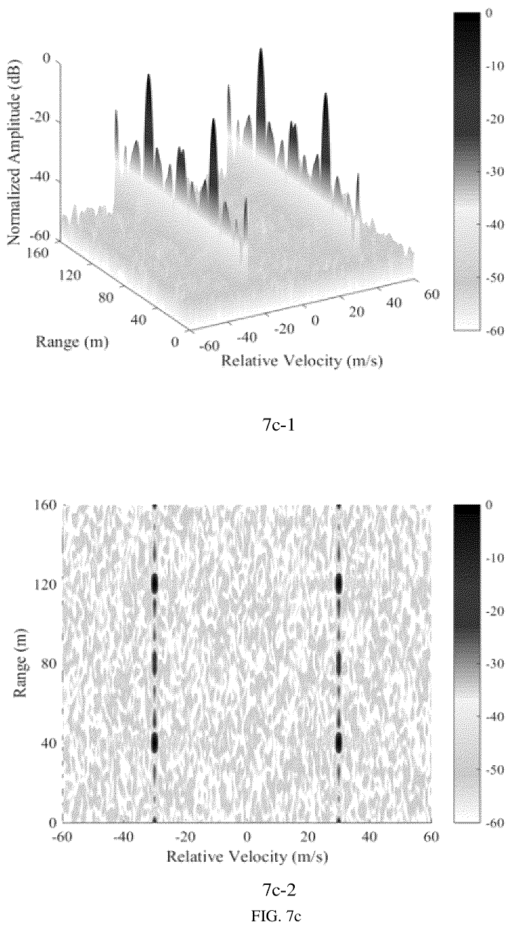

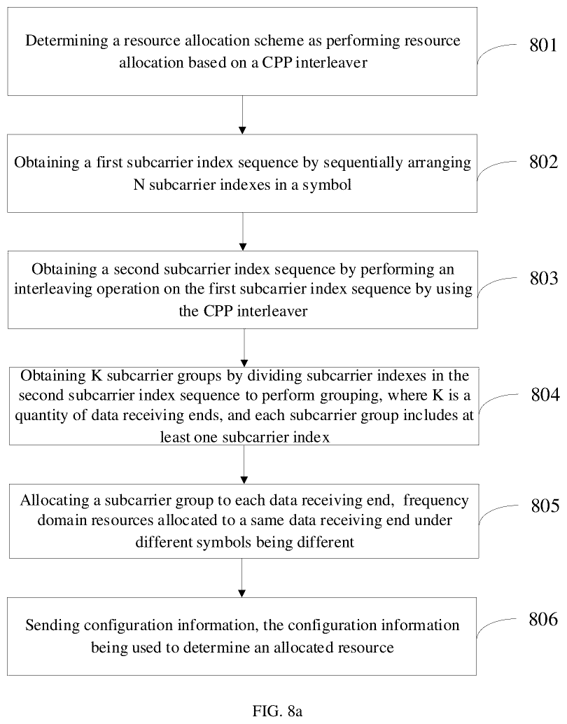

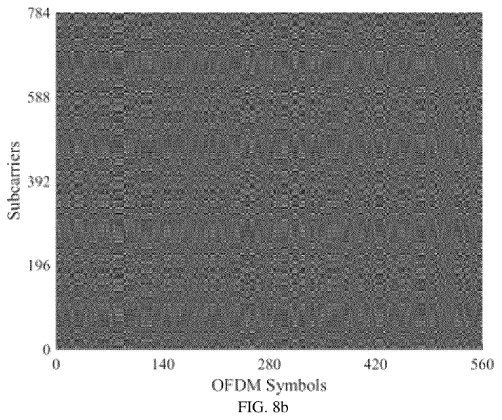

FIG. 8a is a schematic flowchart of a method for resource allocation provided according to some embodiments of the present disclosure. As shown in FIG. 8a, the method for resource allocation may include the following steps.

In step 801, a resource allocation scheme is determined as performing resource allocation based on a CPP interleaver.

In step 802, a first subcarrier index sequence is obtained by sequentially arranging N subcarrier indexes in a symbol.

In step 803, a second subcarrier index sequence is obtained by performing interleaving processing on the first subcarrier index sequence by using the CPP interleaver.

In step 804, K subcarrier groups are obtained by dividing subcarrier indexes in the second subcarrier index sequence to perform grouping, where K is a quantity of data receiving ends in the ISAC system, and each subcarrier group includes at least one first subcarrier index sequence.

For detailed descriptions of steps 801 to 804, reference may be made to the description of the foregoing embodiments, and details are not described here in the embodiments of the present disclosure.

In step 805, a subcarrier group is allocated to each data receiving end, where a subcarrier corresponding to a subcarrier index in each subcarrier group is a frequency domain resource allocated to the data receiving end, and frequency domain resources allocated to the same data receiving end under different symbols are different.

In some embodiments of the present disclosure, it is assumed that the basic parameters of the ISAC system are shown in above Table 1, and it is assumed that there are two UE of A and B in the ISAC system as the data receiving ends, and the velocity and distance information of the two UE are as shown in above Table 2.

Based on the basic parameters in Table 1, it may be determined that UE #A, UE #B, UE #C, and UE #D respectively occupy 196 subcarriers among N=784 subcarriers, and subcarrier indexes of UE #A, UE #B, UE #C, and UE #D are obtained through calculating by a CPP interleaver, and subcarrier indexes of UE #A, UE #B, UE #C, and UE #D are changed within 560 OFDM symbol times. Among them, FIG. 8b is a schematic diagram of time-frequency resources for UE #A when resource allocation is performed by using the method shown in FIG. 8a provided according to embodiments of the present disclosure, where a subcarrier occupied by the UE #A is represented by a white portion, and a subcarrier that is not occupied by the UE #A is represented by a black portion. It should be noted that, FIG. 8b is a schematic diagram obtained when resource allocation is performed based on a CPP interleaver calculation formula in a case that f₁=293, f₂=756, f₃=896, and FIG. 8c is a perspective view and a plan view of radar detection on UE by using the method shown in FIG. 8a provided according to embodiments of the present disclosure, where the perspective view of radar detection is c-1 in FIG. 8c, and the plan view of radar detection plan is c-2 in FIG. 8c. It can be seen from FIG. 8c that, after the frequency domain resource is allocated to the UE by using the allocation mode shown in FIG. 8a, when detecting on the UE, there is no obvious side lobes, the two UE may be distinguished more clearly, with better detection effect.

In step 806, configuration information is sent, where the configuration information is used to determine an allocated resource.

In some embodiments of the present disclosure, the configuration information may include frequency domain resources corresponding to various data receiving end. For example, the configuration information includes that the subcarrier group #1 is a frequency domain resource for the data receiving end #B.

In summary, in the method for resource allocation provided in the embodiments of the present disclosure, a resource allocation scheme is firstly determined as performing resource allocation based on a CPP interleaver; and then, resource allocation is performed according to the resource allocation scheme, and configuration information is sent, where the configuration information is used to determine an allocated resource. It can be seen that, in the embodiments of the present disclosure, a CPP interleaver is introduced when a resource is allocated to a data receiving end, the subcarrier sequence is scrambled by using the CPP interleaver, and the subcarriers are randomly allocated to a plurality of users by constructing a pseudo-random sequence, so that continuous frequency domain resources are prevented from being allocated to the data receiving end, and the sensing capability of the ISAC system is improved, which is more conducive to distinguishing a plurality of moving targets in the ISAC system.

In addition, the execution body of the method in FIG. 5 to FIG. 8a is described by using an example in which the data sending end is a base station and the data receiving end is UE.

In some embodiments of the present disclosure, the method of FIG. 5 to FIG. 8a may be performed by a base station serving as the data sending end; that is, the base station determines the resource allocation scheme as performing resource allocation based on a CPP interleaver, performs resource allocation based on the method for resource allocation, then sends the configuration information for determining the allocated resources to the UE (i.e., the data receiving end), and the UE determines the frequency domain resources allocated to the UE based on the configuration information. Among them, the method for determining the resource allocation scheme by the base station may be at least one of the following: determining the resource allocation scheme based on a protocol agreement, obtaining the a resource allocation scheme sent by a core network device, obtaining the resource allocation scheme sent by another base station (where the resource allocation scheme of another base station is configured by a core network device or configured by another base station), or determining the resource allocation scheme by the base station itself. In addition, it should be noted that, in some embodiments of the present disclosure, the base station serving as the data sending end may further directly send the determined resource allocation scheme to the UE, so that the UE may determine the frequency domain resource allocated to the UE based on the resource allocation scheme.

In some embodiments of the present disclosure, the method in FIG. 5 to FIG. 8a may be performed by a base station serving as a data sending end and UE serving as a data receiving end, respectively. That is, both the base station and the UE determine the resource allocation scheme as performing resource allocation based on a CPP interleaver, and perform resource allocation based on the resource allocation scheme. Among them, the method for determining the resource allocation scheme by the UE may be determining a resource allocation scheme based on a protocol agreement, and/or obtaining, by the UE, the resource allocation scheme sent by the base station.

In some embodiments of the present disclosure, the method in FIG. 5 to FIG. 8a may be performed by another base station (which is different from the base station serving as the data sending end). That is, another base station determines the resource allocation scheme as performing resource allocation based on a CPP interleaver, performs resource allocation based on the resource allocation scheme, and then respectively sends the configuration information to the base station serving as the data sending end and the UE serving as the data receiving end, so that both of them determine the frequency domain resources allocated to the UE.

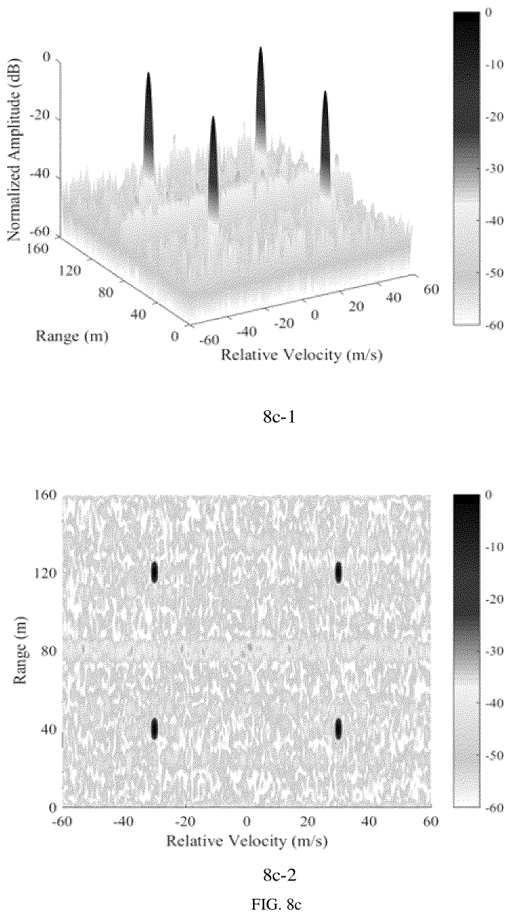

FIG. 9 is a schematic structural diagram of an apparatus for data sending provided according to some embodiments of the present disclosure. As shown in FIG. 9, the apparatus includes a determination module 901, an allocation module 902, and a sending module 903.

The determination module 901 is configured to determine a resource allocation scheme as performing resource allocation based on a CPP interleaver.

The allocation module 902 is configured to perform resource allocation according to the resource allocation scheme.

The sending module 903 is configured to send configuration information, where the configuration information is used to determine an allocated resource.

In summary, in the apparatus provided in the embodiments of the present disclosure, a resource allocation scheme is firstly determined as performing resource allocation based on a CPP interleaver; and then, resource allocation is performed according to the resource allocation scheme, and configuration information is sent, where the configuration information is used to determine an allocated resource. It can be seen that, in the embodiments of the present disclosure, a CPP interleaver is introduced when a resource is allocated to a data receiving end, the subcarrier sequence is scrambled by using the CPP interleaver, and the subcarriers are randomly allocated to a plurality of users by constructing a pseudo-random sequence, so that continuous frequency domain resources are prevented from being allocated to the data receiving end, and the sensing capability of the ISAC system is improved, which is more conducive to distinguishing a plurality of moving targets in the ISAC system.

In some embodiments of the present disclosure, the allocation module is configured to:
obtain a first subcarrier index sequence by sequentially arranging N subcarrier indexes in a symbol;
obtain a second subcarrier index sequence by performing an interleaving operation on the first subcarrier index sequence by using the CPP interleaver;
obtain K subcarrier groups by dividing subcarrier indexes in the second subcarrier index sequence to perform grouping, where K is a quantity of data receiving ends; and
allocate a subcarrier group to each data receiving end, where a subcarrier corresponding to a subcarrier index in each subcarrier group is a frequency domain resource allocated to the data receiving end.

In some embodiments of the present disclosure, the apparatus is further configured to:
determine an interleaving parameter of the CPP interleaver;
where the interleaving parameter of the CPP interleaver includes at least one of following:
a CPP interleaver calculation formula;
a decomposition formula corresponding to the CPP interleaver; or
a parameter value rule in the CPP interleaver calculation formula.

In some embodiments of the present disclosure, the CPP interleaver calculation formula is:

$$π ( i ) = ( {f}_{1} \cdot i + {f}_{2} \cdot {i}^{2} + {f}_{3} \cdot {i}^{3} ) mod N \qquad ( 3 )$$

where, i is used to indicate an ith bit in the second subcarrier index sequence, π(i) is a value of the ith bit in the second subcarrier index sequence, f₁, f₂ and f₃ are three parameters of the CPP interleaver, and values of f₁, f₂ and f₃ are determined based on the parameter value rule.

In some embodiments of the present disclosure, the decomposition formula corresponding to the CPP interleaver is:

$$N = {\prod }_{i = 1}^{ω ( N )} {p}_{i}^{{α}_{N , i}} \qquad ( 4 )$$

where ω(N) is a positive integer, pᵢ is a factor of N, α_{N,i} is a corresponding index.

In some embodiments of the present disclosure, the parameter value rule is as follows.

| | | |
|---|---|---|
| p₁ = 2 | α_{N, 1} = 1 | (f₁ + f₂ + f₃) = 1 mod 2 |
| | α_{N, 1} > 1 | f₁ = 1 mod 2, f₂ = 0 mod 2, f₃ = 0 mod 2 |
| p₂ = 3 | α_{N, 2} = 1 | (f₁ + f₃) ≠ 0 mod 3, f₂ = 0 mod 3 |
| | α_{N, 2} > 1 | f₁ ≠ 0 mod 3, (f₁ + f₃) ≠ 0 mod 3, f₂ = 0 mod 3 |
| 3 \| (pᵢ − 1) | α_{N, i} ≥ 1 | f₁ ≠ 0 mod pᵢ, f₂ = 0 mod pᵢ, f₃ = 0 mod pᵢ |
| 3 ł (pᵢ − 1) | α_{N, i} = 1 | f₂² = 3 · f₁ · f₃ mod pᵢ, if f₃ ≠ 0 mod pᵢ |
| pᵢ > 3 | | f₁ ≠ 0 mod pᵢ, f₂ = 0 mod pᵢ, if f₃ = 0 mod pᵢ |
| | α_{N, i} 1 | f₁ ≠ 0 mod pᵢ, f₂ = 0 mod pᵢ, f₃ = 0 mod pᵢ |

In some embodiments of the present disclosure, the allocation module is configured to:
determine values of pᵢ and α_{N,i} by performing decomposition on the N based on the decomposition formula;
determine values of f₁, f₂ and f₃ based on the parameter value rule and the values of pᵢ and α_{N,i}; and
obtain the second subcarrier index sequence by calculating based on the CPP interleaver calculation formula.

In some embodiments of the present disclosure, the K subcarrier groups satisfy following conditions:
in response to N being divisible by K, a quantity of subcarrier indexes included in each of the K subcarrier groups being the same;
in response to N being not divisible by K, a quantity of subcarrier indexes included in each of d subcarrier groups among the K subcarrier groups being the same, a quantity of subcarrier indexes included in each of other subcarrier groups being the same, and the quantity of subcarrier indexes included in each of the d subcarrier groups is greater than the quantity of subcarrier indexes included in each of the other subcarrier groups by 1, where d is a value obtained by performing a modulo operation on K by using N.

In some embodiments of the present disclosure, frequency domain resources allocated to the same data receiving end under different symbols are the same or different.

In some embodiments of the present disclosure, the determination module is configured to:
obtain the resource allocation scheme sent by a network device; and/or
obtain the resource allocation scheme sent by a base station, where the resource allocation scheme is pre-configured by a core network device to the base station; and/or
obtain the resource allocation scheme sent by a base station, where the resource allocation scheme is pre-configured by another base station to the base station; and/or
determine the resource allocation scheme based on a protocol agreement;
determine the resource allocation scheme by itself.

In some embodiments of the present disclosure, the determination module is configured to:
obtain an interleaving parameter of the CPP interleaver sent by a network device; and/or
obtain an interleaving parameter of the CPP interleaver sent by a base station, where the interleaving parameter of the CPP interleaver is pre-configured by a core network device to the base station; and/or
obtain an interleaving parameter of the CPP interleaver sent by a base station, where the interleaving parameter of the CPP interleaver is pre-configured by another base station to the base station; and/or
determine an interleaving parameter of the CPP interleaver based on a protocol agreement.

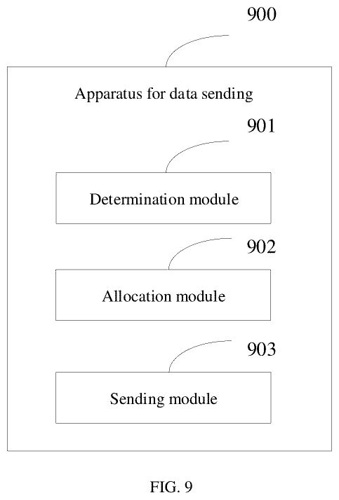

FIG. 10 is a schematic structural diagram of an apparatus for data receiving provided according to some embodiments of the present disclosure. As shown in FIG. 10, the apparatus includes a determination module 1001, an allocation module 1002, and a sending module 1003.

The determination module 100 is configured to determine a resource allocation scheme as performing resource allocation based on a CPP interleaver.

The allocation module 1002 is configured to perform resource allocation according to the resource allocation scheme.

The sending module 1003 is configured to send configuration information, where the configuration information is used to determine an allocated resource.

In summary, in the apparatus provided in the embodiments of the present disclosure, a resource allocation scheme is firstly determined as performing resource allocation based on a CPP interleaver; and then, resource allocation is performed according to the resource allocation scheme, and configuration information is sent, where the configuration information is used to determine an allocated resource. It can be seen that, in the embodiments of the present disclosure, a CPP interleaver is introduced when a resource is allocated to a data receiving end, the subcarrier sequence is scrambled by using the CPP interleaver, and the subcarriers are randomly allocated to a plurality of users by constructing a pseudo-random sequence, so that continuous frequency domain resources are prevented from being allocated to the data receiving end, and the sensing capability of the ISAC system is improved, which is more conducive to distinguishing a plurality of moving targets in the ISAC system.

In some embodiments of the present disclosure, the allocation module is configured to:
obtain a first subcarrier index sequence by sequentially arranging N subcarrier indexes in a symbol;
obtain a second subcarrier index sequence by performing an interleaving operation on the first subcarrier index sequence by using the CPP interleaver;
obtain K subcarrier groups by dividing subcarrier indexes in the second subcarrier index sequence to perform grouping, where K is a quantity of data receiving ends; and
allocate a subcarrier group to each data receiving end, where a subcarrier corresponding to a subcarrier index in each subcarrier group is a frequency domain resource allocated to the data receiving end.

In some embodiments of the present disclosure, the apparatus is further configured to:
determine an interleaving parameter of the CPP interleaver;
where the interleaving parameter of the CPP interleaver includes at least one of following:
a CPP interleaver calculation formula;
a decomposition formula corresponding to the CPP interleaver; or
a parameter value rule in the CPP interleaver calculation formula.

In some embodiments of the present disclosure, the CPP interleaver calculation formula is:

$$π ( i ) = ( {f}_{1} \cdot i + {f}_{2} \cdot {i}^{2} + {f}_{3} \cdot {i}^{3} ) mod N \qquad ( 5 )$$

where, i is used to indicate an ith bit in the second subcarrier index sequence, π(i) is a value of the ith bit in the second subcarrier index sequence, f₁, f₂ and f₃ are three parameters of the CPP interleaver, and values of f₁, f₂ and f₃ are determined based on the parameter value rule.

In some embodiments of the present disclosure, the decomposition formula corresponding to the CPP interleaver is:

$$N = {\prod }_{i = 1}^{ω ( N )} {p}_{i}^{{α}_{N , i}} \qquad ( 6 )$$

where ω(N) is a positive integer, pᵢ is a factor of N, α_{N,i} a is a corresponding index.

In some embodiments of the present disclosure, the parameter value rule is as follows.

| | | |
|---|---|---|
| p₁ = 2 | α_{N, 1} = 1 | (f₁ + f₂ + f₃) = 1 mod 2 |
| | α_{N, 1} > 1 | f₁ = 1 mod 2, f₂ = 0 mod 2, f₃ = 0 mod 2 |
| p₂ = 3 | α_{N, 2} = 1 | (f₁ + f₃) ≠ 0 mod 3, f₂ = 0 mod 3 |
| | α_{N, 2} > 1 | f₁ ≠ 0 mod 3, (f₁ + f₃) ≠ 0 mod 3, f₂ = 0 mod 3 |
| 3 \| (pᵢ − 1) | α_{N, i} ≥ 1 | f₁ ≠ 0 mod pᵢ, f₂ = 0 mod pᵢ, f₃ = 0 mod pᵢ |
| 3 ł (pᵢ − 1) | α_{N, i} = 1 | f₂² = 3 · f₁ · f₃ mod pᵢ, if f₃ ≠ mod pᵢ |
| pᵢ > 3 | | f₁ ≠ 0 mod pᵢ, f₂ = 0 mod pᵢ, if f₃ = 0 mod pᵢ |
| | α_{N, i} > 1 | f₁ ≠ 0 mod pᵢ, f₂ = 0 mod pᵢ, f₃ = 0 mod pᵢ |

In some embodiments of the present disclosure, the allocation module is configured to:
determine values of pᵢ and α_{N,i} by performing decomposition on the N based on the decomposition formula;
determine values of f₁, f₂ and f₃ based on the parameter value rule and the values of pᵢ and α_{N,i}; and
obtain the second subcarrier index sequence by calculating based on the CPP interleaver calculation formula.

In some embodiments of the present disclosure, the K subcarrier groups satisfy following conditions:
in response to N being divisible by K, a quantity of subcarrier indexes included in each of the K subcarrier groups being the same;
in response to N being not divisible by K, a quantity of subcarrier indexes included in each of d subcarrier groups among the K subcarrier groups being the same, a quantity of subcarrier indexes included in each of other subcarrier groups being the same, and the quantity of subcarrier indexes included in each of the d subcarrier groups is greater than the quantity of subcarrier indexes included in each of the other subcarrier groups by 1, where d is a value obtained by performing a modulo operation on K by using N.

In some embodiments of the present disclosure, frequency domain resources allocated to the same data receiving end under different symbols are the same or different.

In some embodiments of the present disclosure, the determination module is configured to:
obtain the resource allocation scheme sent by a network device; and/or
obtain the resource allocation scheme sent by a base station, where the resource allocation scheme is pre-configured by a core network device to the base station; and/or
obtain the resource allocation scheme sent by a base station, where the resource allocation scheme is pre-configured by another base station to the base station; and/or
determine the resource allocation scheme based on a protocol agreement;
determine the resource allocation scheme by itself.

In some embodiments of the present disclosure, the determination module is configured to:
obtain an interleaving parameter of the CPP interleaver sent by a network device; and/or
obtain an interleaving parameter of the CPP interleaver sent by a base station, where the interleaving parameter of the CPP interleaver is pre-configured by a core network device to the base station; and/or
obtain an interleaving parameter of the CPP interleaver sent by a base station, where the interleaving parameter of the CPP interleaver is pre-configured by another base station to the base station; and/or
determine an interleaving parameter of the CPP interleaver based on a protocol agreement.

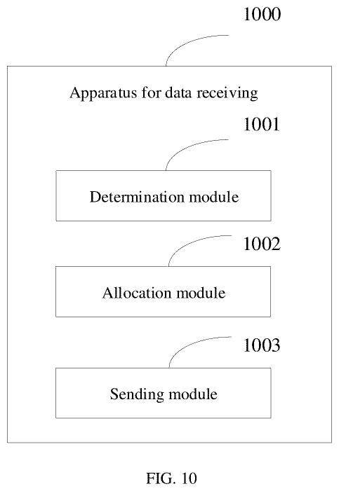

FIG. 11 is a schematic structural diagram of an apparatus for echo receiving provided according to some embodiments of the present disclosure. As shown in FIG. 11, the apparatus includes a determination module 1101, an allocation module 1102, and a sending module 1103.

The determination module 1101 is configured to determine a resource allocation scheme as performing resource allocation based on a CPP interleaver.

The allocation module 1102 is configured to perform resource allocation according to the resource allocation scheme.

The sending module 1103 is configured to send configuration information, where the configuration information is used to determine an allocated resource.

In summary, in the apparatus provided in the embodiments of the present disclosure, a resource allocation scheme is firstly determined as performing resource allocation based on a CPP interleaver; and then, resource allocation is performed according to the resource allocation scheme, and configuration information is sent, where the configuration information is used to determine an allocated resource. It can be seen that, in the embodiments of the present disclosure, a CPP interleaver is introduced when a resource is allocated to a data receiving end, the subcarrier sequence is scrambled by using the CPP interleaver, and the subcarriers are randomly allocated to a plurality of users by constructing a pseudo-random sequence, so that continuous frequency domain resources are prevented from being allocated to the data receiving end, and the sensing capability of the ISAC system is improved, which is more conducive to distinguishing a plurality of moving targets in the ISAC system.

In some embodiments of the present disclosure, the allocation module is configured to:
obtain a first subcarrier index sequence by sequentially arranging N subcarrier indexes in a symbol;
obtain a second subcarrier index sequence by performing an interleaving operation on the first subcarrier index sequence by using the CPP interleaver;
obtain K subcarrier groups by dividing subcarrier indexes in the second subcarrier index sequence to perform grouping, where K is a quantity of data receiving ends; and
allocate a subcarrier group to each data receiving end, where a subcarrier corresponding to a subcarrier index in each subcarrier group is a frequency domain resource allocated to the data receiving end.

In some embodiments of the present disclosure, the apparatus is further configured to:
determine an interleaving parameter of the CPP interleaver;
where the interleaving parameter of the CPP interleaver includes at least one of following:
a CPP interleaver calculation formula;
a decomposition formula corresponding to the CPP interleaver; or
a parameter value rule in the CPP interleaver calculation formula.

In some embodiments of the present disclosure, the CPP interleaver calculation formula is:

$$π ( i ) = ( {f}_{1} \cdot i + {f}_{2} \cdot {i}^{2} + {f}_{3} \cdot {i}^{3} ) mod N \qquad ( 7 )$$

where, i is used to indicate an ith bit in the second subcarrier index sequence, π(i) is a value of the ith bit in the second subcarrier index sequence, f₁, f₂ and f₃ are three parameters of the CPP interleaver, and values of f₁, f₂ and f₃ are determined based on the parameter value rule.

In some embodiments of the present disclosure, the decomposition formula corresponding to the CPP interleaver is:

$$N = {\prod }_{i = 1}^{ω ( N )} {p}_{i}^{{α}_{N , i}} \qquad ( 8 )$$

where ω(N) is a positive integer, pᵢ is a factor of N, α_{N,i} is a corresponding index.

In some embodiments of the present disclosure, the parameter value rule is as follows.

| | | |
|---|---|---|
| p₁ = 2 | α_{N, 1} = 1 | (f₁ + f₂ + f₃) = 1 mod 2 |
| | α_{N, 1} > 1 | f₁ = 1 mod 2, f₂ = 0 mod 2, f₃ = 0 mod 2 |
| p₂ = 3 | α_{N, 2} = 1 | (f₁ + f₃) ≠ 0 mod 3, f₂ = 0 mod 3 |
| | α_{N, 2} > 1 | f₁ ≠ 0 mod 3, (f₁ + f₃) ≠ 0 mod 3, f₂ = 0 mod 3 |
| 3 \| (pᵢ − 1) | α_{N, i} ≥ 1 | f₁ ≠ 0 mod pᵢ, f₂ = 0 mod pᵢ, f₃ = 0 mod pᵢ |
| 3 ł (pᵢ − 1) | α_{N, i} = 1 | f₂² = 3 · f₁ · f₃ mod pᵢ, if f₃ ≠ mod pᵢ |
| pᵢ > 3 | | f₁ ≠ 0 mod pᵢ, f₂ = 0 mod pᵢ, if f₃ = 0 mod pᵢ |
| | α_{N, i} > 1 | f₁ ≠ 0 mod pᵢ, f₂ = 0 mod pᵢ, f₃ = 0 mod pᵢ |

In some embodiments of the present disclosure, the allocation module is configured to:
determine values of pᵢ and α_{N,i} by performing decomposition on the N based on the decomposition formula;
determine values of f₁, f₂ and f₃ based on the parameter value rule and the values of pᵢ and α_{N,i}; and
obtain the second subcarrier index sequence by calculating based on the CPP interleaver calculation formula.

In some embodiments of the present disclosure, the K subcarrier groups satisfy following conditions:
in response to N being divisible by K, a quantity of subcarrier indexes included in each of the K subcarrier groups being the same;
in response to N being not divisible by K, a quantity of subcarrier indexes included in each of d subcarrier groups among the K subcarrier groups being the same, a quantity of subcarrier indexes included in each of other subcarrier groups being the same, and the quantity of subcarrier indexes included in each of the d subcarrier groups is greater than the quantity of subcarrier indexes included in each of the other subcarrier groups by 1, where d is a value obtained by performing a modulo operation on K by using N.

In some embodiments of the present disclosure, frequency domain resources allocated to the same data receiving end under different symbols are the same or different.

In some embodiments of the present disclosure, the determination module is configured to:
obtain the resource allocation scheme sent by a network device; and/or
obtain the resource allocation scheme sent by a base station, where the resource allocation scheme is pre-configured by a core network device to the base station; and/or
obtain the resource allocation scheme sent by a base station, where the resource allocation scheme is pre-configured by another base station to the base station; and/or
determine the resource allocation scheme based on a protocol agreement;
determine the resource allocation scheme by itself.

In some embodiments of the present disclosure, the determination module is configured to:
obtain an interleaving parameter of the CPP interleaver sent by a network device; and/or
obtain an interleaving parameter of the CPP interleaver sent by a base station, where the interleaving parameter of the CPP interleaver is pre-configured by a core network device to the base station; and/or
obtain an interleaving parameter of the CPP interleaver sent by a base station, where the interleaving parameter of the CPP interleaver is pre-configured by another base station to the base station; and/or
determine an interleaving parameter of the CPP interleaver based on a protocol agreement.

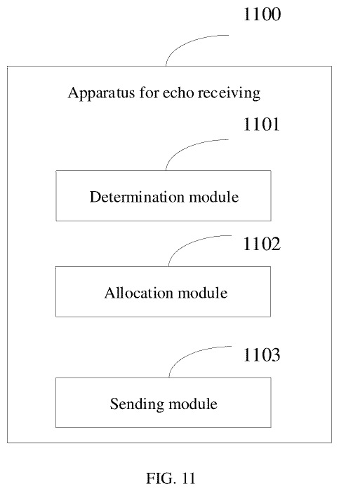

FIG. 12 is a block diagram of user equipment (UE) 1200 provided according to some embodiments of the present disclosure. For example, the UE 1200 may be a mobile phone, a computer, a digital broadcast terminal device, a message transceiving device, a game console, a tablet device, a medical device, an exercise device, a personal digital assistant, or the like.

Referring to FIG. 12, the UE 1200 may include at least one of the following components: a processing component 1202, a memory 1204, a power component 1206, a multimedia component 1208, an audio component 1210, an input/output (I/O) interface 1212, a sensor component 1214, and a communication component 1216.

The processing component 1202 generally controls overall operations of the UE 1200, such as operations associated with display, telephone calls, data communications, camera operations, and recording operations. The processing component 1202 may include at least one processor 1220 to execute instructions to perform all or part of the steps in the foregoing methods. In addition, the processing component 1202 may include at least one module, which facilitates interaction between the processing component 1202 and other components. For example, the processing component 1202 may include a multimedia module to facilitate the interaction between the multimedia component 1208 and the processing component 1202.

The memory 1204 is configured to store various types of data to support operations at the UE 1200. Examples of such data include instructions for any application or method operating on the UE 1200, contact data, phonebook data, messages, pictures, videos, etc. The memory 1204 may be implemented by any type of volatile or non-volatile storage device or a combination of them, such as a static random access memory (SRAM), an electrically erasable programmable read-only memory (EEPROM), an erasable programmable read-only memory (EPROM), a programmable read-only memory (PROM), a read-only memory (ROM), a magnetic memory, a flash memory, a magnetic disk, or an optical disk.

The power component 1206 provides power to various components of the UE 1200. The power component 1206 may include a power management system, at least one power supply, and other components associated with generating, managing, and distributing power for the UE 1200.

The multimedia component 1208 includes a screen providing an output interface between the UE 1200 and the user. In some embodiments, the screen may include a liquid crystal display (LCD) and a touch panel (TP). If the screen includes the touch panel, the screen may be implemented as a touch screen to receive input signals from the user. The touch panel includes at least one touch sensor to sense touching, sliding, and gestures on the touch panel. The touch sensor may not only sense a boundary of a touching or sliding action, but also detect a wake-up time and a pressure associated with the touching or sliding action. In some embodiments, the multimedia component 1208 includes a front camera and/or a rear camera. When the UE 1200 is in an operation mode, such as a photographing mode or a video mode, the front camera and/or the rear camera may receive external multimedia data. Each of the front camera and the rear camera may be a fixed optical lens system or have focal length and optical zoom capability.

The audio component 1210 is configured to output and/or input audio signals. For example, the audio component 1210 includes a microphone (MIC) configured to receive an external audio signal when the UE 1200 is in an operation mode, such as a call mode, a recording mode, and a speech recognition mode. The received audio signal may be further stored in the memory 1204 or transmitted via the communication component 1216. In some embodiments, the audio component 1210 further includes a speaker to output audio signals.

The I/O interface 1212 provides an interface between the processing component 1202 and a peripheral interface module, and the peripheral interface module may be a keyboard, a click wheel, a button, or the like. The button may include, but are not limited to, a home button, a volume button, a starting button, and a locking button.

The sensor component 1213 includes at least one sensor for providing status assessments of various aspects of the UE 1200. For example, the sensor component 1213 may detect an on/off state of the UE 1200 and relative positioning of the components; for example, the components are a display and a keypad of the UE 1200. The sensor component 1213 may also detect a position change of the UE 1200 or of a component of the UE 1200, a presence or absence of contact by the user with the UE 1200, an orientation or acceleration/deceleration of the UE 1200, and a temperature change of the UE 1200. The sensor component 1213 may include a proximity sensor configured to detect the presence of nearby objects without any physical contact. The sensor component 1213 may also include a optical sensor, such as a CMOS or CCD image sensor, for use in imaging applications. In some embodiments, the sensor component 1213 may further include an acceleration sensor, a gyroscope sensor, a magnetic sensor, a pressure sensor, or a temperature sensor.

The communication component 1216 is configured to facilitate wired or wireless communication between the UE 1200 and other devices. The UE 1200 may access a wireless network based on a communication standard, such as WiFi, 2G, or 3G, or a combination of them. In some embodiments, the communication component 1216 receives a broadcast signal or broadcast related information from an external broadcast management system via a broadcast channel. In some embodiments, the communication component 1216 further includes a near field communication (NFC) module to facilitate short-range communications. For example, the NFC module may be implemented based on a radio frequency identification (RFID) technology, an infrared data association (IrDA) technology, an ultra-wideband (UWB) technology, a Bluetooth (BT) technology, and other technologies.

In some embodiments, the UE 1200 may be implemented by at least one application specific integrated circuit (ASIC), a digital signal processor (DSP), a digital signal processing device (DSPD), a programmable logic device (PLD), a field programmable gate array (FPGA), a controller, a microcontroller, a microprocessor, or other electronic components for performing the methods described above.

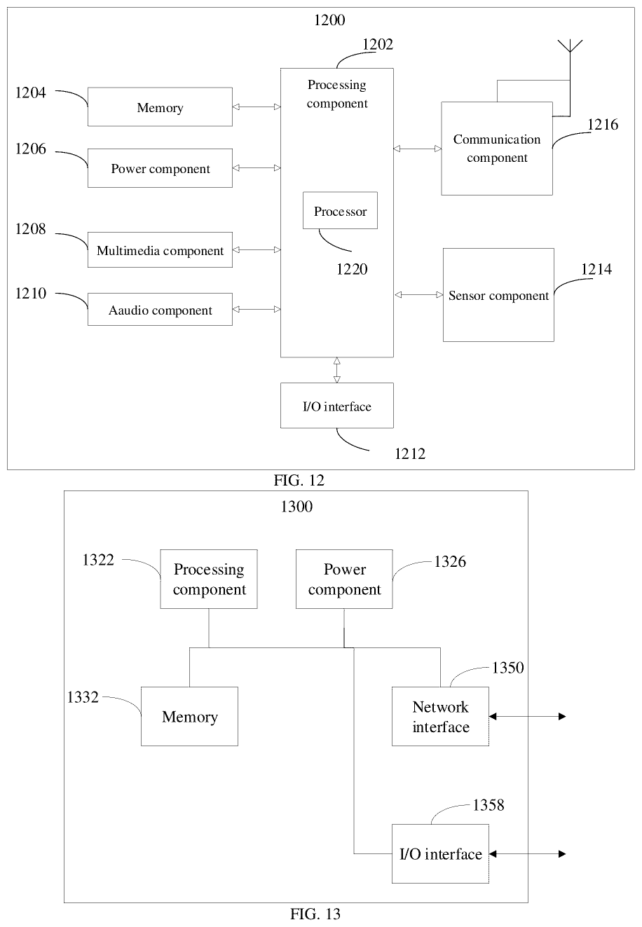

FIG. 13 is a block diagram of a network side device 1300 provided according to some embodiments of the present disclosure. For example, the network side device 1300 may be provided as a network side device. Referring to FIG. 13, the network side device 1300 includes a processing component 1311 that further includes at least one processor, and memory resources represented by the memory 1332 for storing instructions, such as an application, executable by the processing component 1322. The application program stored in the memory 1332 may include one or more modules each corresponding to a set of instructions. In addition, the processing component 1310 is configured to execute instructions to perform any method of the foregoing method applied to the network side device, for example, the method as shown in FIG. 5.

The network side device 1300 may further include a power component 1326 configured to perform power management of the network side device 1300, a wired or wireless network interface 1350 configured to connect the network side device 1300 to a network, and an input/output (I/O) interface 1358. The network side device 1300 may be operated based on an operating system stored in the memory 1332, such as Windows Server™, MAC OS X™, Unix™, Linux™, Free BSDT™, or the like.

In the foregoing embodiments provided in the present disclosure, the methods provided in the embodiments of the present disclosure are separately described from the perspective of the network side device and from the perspective of UE, respectively. To implement the various functions in the method provided in the foregoing embodiments of the present disclosure, the network side device or the UE may include a hardware structure and a software module, to implement the foregoing functions in a form of a hardware structure, a software module, or a hardware structure plus software module. A function in the foregoing functions may be performed by using a hardware structure, a software module, or a hardware structure plus a software module.

According to some embodiments of the present disclosure, there is provided a communication apparatus. The communication apparatus may include a transceiving module and a processing module. The transceiving module may include a sending module and/or a receiving module, the sending module is configured to implement a sending function, the receiving module is configured to implement a receiving function, and the transceiving module may implement a sending function and/or a receiving function.

The communication apparatus may be a terminal device (for example, the terminal device in the foregoing method embodiments), an apparatus in the terminal device, or an apparatus that can be used in conjunction with the terminal device. Alternatively, the communication apparatus may be a network device, an apparatus in the network device, or an apparatus that can be used in conjunction with the network device.

According to embodiments of the present disclosure, there is provided another communication apparatus. The communication apparatus may be a network device, or may be a terminal device (for example, a terminal device in the foregoing method embodiments), or may be a chip, a chip system, or a processor, or the like that supports the network device to implement the foregoing method, or may be a chip, a chip system, a processor, or the like that supports the terminal device in implementing the foregoing method. The apparatus may be configured to implement the method described in the foregoing method embodiments. For details, reference may be made to the descriptions in the foregoing method embodiments.

The communication apparatus may include one or more processors. The processor may be a general-purpose processor, a dedicated processor, or the like. For example, the processor may be a baseband processor or a central processing unit. The baseband processor may be configured to process a communication protocol and communication data, and the central processing unit may be configured to control the communication apparatus (for example, a network side device, a baseband chip, a terminal device, a terminal device chip, a DU, or a CU), execute a computer program, and process data of the computer program.

In some embodiments, the communication apparatus may further include one or more memories, on which a computer program may be stored, and the processor executes the computer program to cause the communication apparatus to perform the method described in the foregoing method embodiments. In some embodiments, the memory may further store data. The communication apparatus and the memory may be separately disposed, or may be integrated together.

In some embodiments, the communication apparatus may further include a transceiver and an antenna. The transceiver may be referred to as a transceiving unit, a transceiving device, a transceiving circuit, or the like, and is configured to implement a transceiving function. The transceiver may include a receiver and a transmitter; the receiver may be referred to as a receiving device or a receiving circuit, and is configured to implement a receiving function; and the transmitter may be referred to as a transmitting device or a transmitting circuit, and is configured to implement a transmitting function.

In some embodiments, the communication apparatus may further include one or more interface circuits. The interface circuit is configured to receive a code instruction and transmit the code instruction to the processor. The processor runs the code instruction to cause the communication apparatus to perform the method described in the foregoing method embodiments.

In some embodiments, the processor may include a transceiver configured to implement a receiving and transmitting function. For example, the transceiver may be a transceiving circuit, an interface, or an interface circuit. The transceiving circuit, the interface, or the interface circuit configured to implement the receiving and transmitting function may be separate, or may be integrated together. The transceiving circuit, the interface, or the interface circuit may be configured to read/write code/data; or, the transceiving circuit, the interface, or the interface circuit may be configured to transmit or deliver a signal.

In some embodiments, the processor may store a computer program, and the computer program runs on the processor to cause the communication apparatus to perform the method described in the foregoing method embodiments. The computer program may be cured in the processor, in which case the processor may be implemented by hardware.

In some embodiments, the communication apparatus may include a circuit, and the circuit may implement a function of transmitting or receiving or communicating in the foregoing method embodiments. The processor and the transceiver described in the present disclosure may be implemented on an integrated circuit (IC), an analog IC, a radio frequency integrated circuit (RFIC), a mixed signal IC, an application specific integrated circuit (ASIC), a printed circuit board (PCB), an electronic device, or the like. The processor and the transceiver may also be fabricated using various IC process technologies, such as complementary metal oxide semiconductor (CMOS), nMetal-oxide-semiconductor (NMOS), positive channel metal oxide semiconductor (PMOS), bipolar junction transistor (BJT), bipolar CMOS (BiCMOS), silicon germanium (SiGe), gallium arsenide (GaAs), etc.

The communication apparatus in the foregoing embodiments may be a network device or a terminal device (for example, the terminal device in the foregoing method embodiments); however, the scope of the communication apparatus described in the present disclosure is not limited to this, and the structure of the communication apparatus may not be limited. The communication apparatus may be an independent device or may be part of a larger device. For example, the communication apparatus may be:
(1) an independent integrated circuit IC, or a chip, or a chip system or subsystem;
(2) a set having one or more ICs, optionally, the IC set may also include a storage component for storing data and a computer program;
(3) an ASIC, such as a modem;
(4) a module that can be embedded in other devices;
(5) a receiver, a terminal device, a smart terminal device, a cellular phone, a wireless device, a handset, a mobile unit, a vehicle-mounted device, a network device, a cloud device, an artificial intelligence device, or the like;
(6) other devices, or the like.

For the case that the communication apparatus may be a chip or a chip system, the chip includes a processor and an interface. Among them, there may be one or more processors, and there may be a plurality of interfaces.

In some embodiments, the chip further includes a memory, and the memory is configured to store necessary computer programs and data.

Those skilled in the art may further understand that various illustrative logical blocks and steps listed in the embodiments of the present disclosure may be implemented by electronic hardware, computer software, or a combination of the both. Whether such function is implemented by hardware or software depends upon the particular applications and design requirements of the overall system. Those skilled in the art may use various methods to implement the functions for each particular application, but it should not be understood that the implementation goes beyond the protection scope of the embodiments of the present disclosure.

The present disclosure further provides a readable storage medium, on which an instruction is stored; when the instruction is executed by a computer, the functions of any one of the above method embodiments are implemented.

The present disclosure further provides a computer program product; when the computer program product is executed by a computer, the functions of any one of the above method embodiments are implemented.

All or some of the foregoing embodiments may be implemented by using software, hardware, firmware, or any combination of them. When software is used to implement the embodiments, all or some of the embodiments may be implemented in a form of a computer program product. The computer program product includes one or more computer programs. When the computer program is loaded and executed on a computer, the procedures or functions according to the embodiments of the present disclosure are all or partially generated. The computer may be a general-purpose computer, a dedicated computer, a computer network, or another programmable apparatus. The computer program may be stored in a computer-readable storage medium or transmitted from one computer-readable storage medium to another computer-readable storage medium. For example, the computer program may be transmitted from a website, computer, server, or data center to another website, computer, server, or data center in a wired manner (for example, a coaxial cable, an optical fiber, a digital subscriber line (DSL)), or a wireless manner (for example, infrared, wireless, microwave, or the like). The computer-readable storage medium may be any usable medium accessible by a computer, or a data storage device, such as a server or a data center, integrating one or more usable medium. The usable medium may be a magnetic medium (for example, a floppy disk, a hard disk, or a magnetic tape), an optical medium (for example, a high-density digital video disk (DVD)), a semiconductor medium (for example, a solid state disk (SSD)), or the like.

In the embodiments of the present disclosure, a resource allocation scheme is firstly determined as performing resource allocation based on a CPP interleaver; and then, resource allocation is performed according to the resource allocation scheme, and configuration information is sent, where the configuration information is used to determine an allocated resource. It can be seen that, in the embodiments of the present disclosure, a CPP interleaver is introduced when a resource is allocated to a data receiving end, the subcarrier sequence is scrambled by using the CPP interleaver, and the subcarriers are randomly allocated to a plurality of users by constructing a pseudo-random sequence, so that continuous frequency domain resources are prevented from being allocated to the data receiving end, and the sensing capability of the ISAC system is improved, which is more conducive to distinguishing a plurality of moving targets in the ISAC system.

Those of ordinary skill in the art may understand that various numerical numbers, such as “first” and “second”, involved in the present disclosure, are merely for distinguishing to facilitate description, not intended to limit the scope of the embodiments of the present disclosure, and also do not represent a sequential order.

“At least one” in the present disclosure may also be described as “one or more”, and “a plurality” may be two, three, four, or more, which is not limited in the present disclosure. In the embodiments of the present disclosure, for a kind of technical features, technical features in the kind of technical features are distinguished by “first”, “second”, “third”, “A”, “B”, “C” and “D”, etc. The technical features described by “first”, “second”, “third”, “A”, “B”, “C” and “D” do not have a sequential order or a size order.

Other embodiments of the present disclosure will be apparent to those skilled in the art from consideration of the specification and practice of the present disclosure. The present disclosure is intended to cover any variations, uses, or adaptations of the present disclosure following the general principles of the present disclosure and including common general knowledge and conventional technical means in the art not disclosed in the present disclosure. It is intended that the specification and embodiments may be considered as examples only, with a true scope and spirit of the present disclosure being indicated by the following claims.

It should be understood that the present disclosure is not limited to the precise structures that have been described above and shown in the accompanying drawings, and various modifications and changes may be made without departing from the scope of the present disclosure. It is intended that the scope of the present disclosure only be limited by the appended claims.

1. A method for resource allocation, applied to user equipment or a network side device, and comprising:
determining a resource allocation scheme, the resource allocation scheme being performing resource allocation based on a cubic permutation polynomial (CPP) interleaver;
performing resource allocation according to the resource allocation scheme; and
sending configuration information, wherein the configuration information is used to determine an allocated resource.

2. The method according to claim 1, wherein performing resource allocation according to the resource allocation scheme comprises:
obtaining a first subcarrier index sequence by sequentially arranging N subcarrier indexes in a symbol;
obtaining a second subcarrier index sequence by performing an interleaving operation on the first subcarrier index sequence by using the CPP interleaver;
obtaining K subcarrier groups by dividing subcarrier indexes in the second subcarrier index sequence to perform grouping, wherein K is a quantity of data receiving ends; and
allocating a subcarrier group to a data receiving end, wherein a subcarrier corresponding to a subcarrier index in the subcarrier group is a frequency domain resource allocated to the data receiving end.

3. The method according to claim 2, further comprising:
determining an interleaving parameter of the CPP interleaver;
wherein the interleaving parameter of the CPP interleaver comprises at least one of:
a CPP interleaver calculation formula;
a decomposition formula corresponding to the CPP interleaver; or
a parameter value rule in the CPP interleaver calculation formula.

4. The method according to claim 3, wherein the CPP interleaver calculation formula is:
$$π ( i ) = ( {f}_{1} \cdot i + {f}_{2} \cdot {i}^{2} + {f}_{3} \cdot {i}^{3} ) mod N ,$$
wherein, i is used to indicate an i^{th} bit in the second subcarrier index sequence, π(i) is a value of the i^{th} bit in the second subcarrier index sequence, f₁, f₂ and f₃ are three parameters of the CPP interleaver, and values of f₁, f₂ and f₃ are determined based on the parameter value rule.

5. The method according to claim 3, wherein the decomposition formula corresponding to the CPP interleaver is:
$$N = {\prod }_{i = 1}^{ω ( N )} {p}_{i}^{{α}_{N , i}} ,$$
wherein ω(N) is a positive integer, pᵢ is a factor of N, α_{N,i} is a corresponding index.

6. The method according to claim 3, wherein the parameter value rule is:

| | | |
|---|---|---|
| p₁ = 2 | α_{N, 1} = 1 | (f₁ + f₂ + f₃) = 1 mod 2 |
| | α_{N, 1} > 1 | f₁ = 1 mod 2, f₂ = 0 mod 2, f₃ = 0 mod 2 |
| p₂ = 3 | α_{N, 2} = 1 | (f₁ + f₃) ≠ 0 mod 3, f₂ = 0 mod 3 |
| | α_{N, 2} > 1 | f₁ ≠ 0 mod 3, (f₁ + f₃) ≠ 0 mod 3, f₂ = 0 mod 3 |
| 3 \| (pᵢ − 1) | α_{N, i} ≥ 1 | f₁ ≠ 0 mod pᵢ, f₂ = 0 mod pᵢ, f₃ = 0 mod pᵢ |
| 3 ł (pᵢ − 1) | α_{N, i} = 1 | f₂² = 3 · f₁ · f₃ mod pᵢ, if f₃ ≠ 0 mod pᵢ |
| pᵢ > 3 | | f₁ ≠ 0 mod pᵢ, f₂ = 0 mod pᵢ, if f₃ = 0 mod pᵢ |
| | α_{N, i} > 1 | f₁ ≠ 0 mod pᵢ, f₂ = 0 mod pᵢ, f₃ = 0 mod pᵢ |

7. The method according to claim 4, wherein performing the interleaving operation on the first subcarrier index sequence by using the CPP interleaver comprises:
determining values of pᵢ and α_{N,i} by performing decomposition on the N based on the decomposition formula;
determining values of f₁, f₂ and f₃ based on the parameter value rule and the values of pᵢ and α_{N,i}; and
obtaining the second subcarrier index sequence by calculating based on the CPP interleaver calculation formula.

8. The method according to claim 2, wherein the K subcarrier groups satisfy one of following conditions:
in response to N being divisible by K, a quantity of subcarrier indexes comprised in a subcarrier group of the K subcarrier groups being the same; or
in response to N being not divisible by K, a quantity of subcarrier indexes comprised in a subcarrier group of d subcarrier groups among the K subcarrier groups being the same, a quantity of subcarrier indexes comprised in a subcarrier group of other subcarrier groups being the same, and the quantity of subcarrier indexes comprised in the subcarrier group of the d subcarrier groups is greater than the quantity of subcarrier indexes comprised in the subcarrier group of the other subcarrier groups by 1, wherein d is a value obtained by performing a modulo operation on K by using N.

9. The method according to claim 2, wherein frequency domain resources allocated to a same data receiving end under different symbols are the same or different.

10. The method according to claim 1, wherein determining the resource allocation scheme comprises at least one of:
obtaining the resource allocation scheme sent by a network device;
obtaining the resource allocation scheme sent by a base station, wherein the resource allocation scheme is pre-configured by a core network device to the base station;
obtaining the resource allocation scheme sent by a base station, wherein the resource allocation scheme is pre-configured by another base station to the base station;
determining the resource allocation scheme based on a protocol agreement; or
determining the resource allocation scheme by itself.

11. The method according to claim 3, wherein determining the interleaving parameter of the CPP interleaver comprises at least one of:
obtaining an interleaving parameter of the CPP interleaver sent by a network device;
obtaining an interleaving parameter of the CPP interleaver sent by a base station, wherein the interleaving parameter of the CPP interleaver is pre-configured by a core network device to the base station;
obtaining an interleaving parameter of the CPP interleaver sent by a base station, wherein the interleaving parameter of the CPP interleaver is pre-configured by another base station to the base station; or
determining an interleaving parameter of the CPP interleaver based on a protocol agreement.

12.-14. (canceled)

15. A communication apparatus, comprising:
a processor; and
a memory storing a computer program executable by the processor;
wherein the processor is configured to:
determine a resource allocation scheme, the resource allocation scheme being performing resource allocation based on a cubic permutation polynomial (CPP) interleaver;
perform resource allocation according to the resource allocation scheme; and
send configuration information, wherein the configuration information is used to determine an allocated resource.

16. (canceled)

17. A non-transitory computer-readable storage medium storing an instruction that, when executed by a processor, causes the processor to perform a method according for resource allocation, the method comprising:
determining a resource allocation scheme, the resource allocation scheme being performing resource allocation based on a cubic permutation polynomial (CPP) interleaver;
performing resource allocation according to the resource allocation scheme; and
sending configuration information, wherein the configuration information is used to determine an allocated resource.

18. The communication apparatus according to claim 15, wherein the processor is further configured to:
obtain a first subcarrier index sequence by sequentially arranging N subcarrier indexes in a symbol;
obtain a second subcarrier index sequence by performing an interleaving operation on the first subcarrier index sequence by using the CPP interleaver;
obtain K subcarrier groups by dividing subcarrier indexes in the second subcarrier index sequence to perform grouping, wherein K is a quantity of data receiving ends; and
allocate a subcarrier group to a data receiving end, wherein a subcarrier corresponding to a subcarrier index in the subcarrier group is a frequency domain resource allocated to the data receiving end.

19. The communication apparatus according to claim 18, wherein the processor is further configured to:
determine an interleaving parameter of the CPP interleaver;
wherein the interleaving parameter of the CPP interleaver comprises at least one of:
a CPP interleaver calculation formula;
a decomposition formula corresponding to the CPP interleaver; or
a parameter value rule in the CPP interleaver calculation formula.

20. The communication apparatus according to claim 19, wherein the CPP interleaver calculation formula is:
$$π ( i ) = ( {f}_{1} \cdot i + {f}_{2} \cdot {i}^{2} + {f}_{3} \cdot {i}^{3} ) mod N ,$$
wherein, i is used to indicate an i^{th} bit in the second subcarrier index sequence, π(i) is a value of the i^{th} bit in the second subcarrier index sequence, f₁, f₂ and f₃ are three parameters of the CPP interleaver, and values of f₁, f₂ and f₃ are determined based on the parameter value rule.

21. The communication apparatus according to claim 19, wherein the decomposition formula corresponding to the CPP interleaver is:
$$N = {\prod }_{i = 1}^{ω ( N )} {p}_{i}^{{α}_{N , i}} ,$$
wherein ω(N) is a positive integer, pᵢ is a factor of N, α_{N,i} is a corresponding index.

22. The communication apparatus according to claim 19, wherein the parameter value rule is:

| | | |
|---|---|---|
| p₁ = 2 | α_{N, 1} = 1 | (f₁ + f₂ + f₃) = 1 mod 2 |
| | α_{N, 1} > 1 | f₁ = 1 mod 2, f₂ = 0 mod 2, f₃ = 0 mod 2 |
| p₂ = 3 | α_{N, 2} = 1 | (f₁ + f₃) ≠ 0 mod 3, f₂ = 0 mod 3 |
| | α_{N, 2} > 1 | f₁ ≠ 0 mod 3, (f₁ + f₃) ≠ 0 mod 3, f₂ = 0 mod 3 |
| 3 \| (pᵢ − 1) | α_{N, i} = 1 | f₁ ≠ 0 mod pᵢ, f₂ = 0 mod pᵢ, f₃ = 0 mod pᵢ |
| 3 ł (pᵢ − 1) | α_{N, i} = 1 | f₂² = 3 · f₁ · f₃ mod pᵢ, if f₃ ≠ 0 mod pᵢ |
| | | f₁ ≠ 0 mod pᵢ, f₂ = 0 mod pᵢ, if f₃ = 0 mod pᵢ |
| pᵢ > 3 | α_{N, i} > 1 | f₁ ≠ 0 mod pᵢ, f₂ = 0 mod pᵢ, f₃ = 0 mod pᵢ |

23. The communication apparatus according to claim 20, wherein the processor is further configured to:
determine values of pᵢ and α_{N,i} by performing decomposition on the N based on the decomposition formula;
determine values of f₁, f₂ and f₃ based on the parameter value rule and the values of pᵢ and α_{N,1}; and
obtain the second subcarrier index sequence by calculating based on the CPP interleaver calculation formula.

24. The communication apparatus according to claim 18, wherein the K subcarrier groups satisfy one of following conditions:
in response to N being divisible by K, a quantity of subcarrier indexes comprised in a subcarrier group of the K subcarrier groups being the same; or
in response to N being not divisible by K, a quantity of subcarrier indexes comprised in a subcarrier group of d subcarrier groups among the K subcarrier groups being the same, a quantity of subcarrier indexes comprised in a subcarrier group of other subcarrier groups being the same, and the quantity of subcarrier indexes comprised in the subcarrier group of the d subcarrier groups is greater than the quantity of subcarrier indexes comprised in the subcarrier group of the other subcarrier groups by 1, wherein d is a value obtained by performing a modulo operation on K by using N.
